(19) United States
(12) Patent Application Publication
(10) Pub. No.: US 2013/0270601 A1
(43) Pub. Date: Oct. 17, 2013

(54) PACKAGE STRUCTURE OF SEMICONDUCTOR LIGHT EMITTING DEVICE

(71) Applicant: LEXTAR ELECTRONICS CORPORATION, Hsinchu (TW)

(72) Inventors: Kuan-Chieh Wang, Taitung City (TW); Zong-Han Yu, Keelung City (TW)

(73) Assignee: Lextar Electronics Corporation, Hsinchu (TW)

(21) Appl. No.: 13/858,123

(22) Filed: Apr. 8, 2013

(30) Foreign Application Priority Data
Apr. 12, 2012 (TW) 101206732

(51) Int. Cl. H01L 33/62

(52) U.S. Cl. CPC H01L 33/62
USPC 257/99

(57) ABSTRACT

A package structure of a semiconductor light emitting device is provided. The packaging structure comprises a substrate, a circuit board, a semiconductor light emitting device and a coating layer is provided. The circuit board has an opening portion disposed on the substrate for exposing a surface of the substrate. The semiconductor light emitting device is disposed on the surface of the substrate exposed by the opening portion. The coating layer covers the sidewalls of the opening portion and the circuit board.

This application claims the benefit of Taiwan application Serial No. 101206732, filed Apr. 12, 2012, the subject matter of which is incorporated herein by reference.

### BACKGROUND OF THE INVENTION

1. Field of the Invention

The invention relates in general to a package structure of a semiconductor device, and more particularly to a package structure of a solid-state semiconductor light emitting device.

2. Description of the Related Art

The light-emitting diode (LED) emits a light by converting electric energy into photo energy. The LED is mainly composed of semiconductors, and is an ideal solid-state light emitting device. The conventional light emitting diode is placed on a heat dissipating substrate for increasing thermal performance. Normally, after the light emitting diode is packaged, the light emitting diode is heated at a high temperature and goes through a lighting test to assure the packaging quality. However, the brightness of the light emitted from the light emitting diode decays apparently due to the burn-in test. Therefore, the package structure of light emitting diode needs to be improved to resolve the decay problem.

### SUMMARY OF THE INVENTION

The invention is directed to a package structure of a semiconductor light emitting device, which avoids the dielectric layer being deteriorated or etiolated and resolves the problem of decay in brightness.

According to an embodiment of the present invention, a package structure of a semiconductor light emitting device is provided. The package structure comprises a substrate, a circuit board, a semiconductor light emitting device and a coating layer. The circuit board is disposed on the substrate and has an opening portion for exposing a surface of the substrate. The semiconductor light emitting device is disposed on the surface exposed by the opening portion. The coating layer covers the sidewalls of the opening portion and the circuit board.

The above and other aspects of the invention will become better understood with regard to the following detailed description of the preferred but non-limiting embodiment(s). The following description is made with reference to the accompanying drawings.

### BRIEF DESCRIPTION OF THE DRAWINGS

FIG. 1 shows a package structure of a semiconductor light emitting device according to an embodiment of the invention.

### DETAILED DESCRIPTION OF THE INVENTION

In the package structure of a semiconductor light emitting device of the present embodiment, a coating layer is formed on the sidewalls of the opening portion of the circuit board to avoid the sidewalls of the circuit board being exposed in a high temperature environment and becoming deteriorated or etiolated, such that the light emitted by the semiconductor light emitting device will not decay and the light extraction efficiency can be improved. In an embodiment of the invention, the coating layer, being a metal plating layer (such as silver or nickel) or a polymer layer (such as silicone), at least covers the sidewalls of the opening portion of the circuit board, and the semiconductor light emitting device is disposed in the opening portion. Through such arrangement, the brightness of the light emitted by the semiconductor light emitting device will not be affected by the deterioration of the circuit board and decay. Besides, the coating layer can be a metal layer with high reflectivity to improve the light extraction efficiency of the semiconductor light emitting device and increase the luminous flux.

A number of embodiments are disclosed below for elaborating the invention. However, the embodiments of the invention are for detailed descriptions only, not for limiting the scope of protection of the invention.

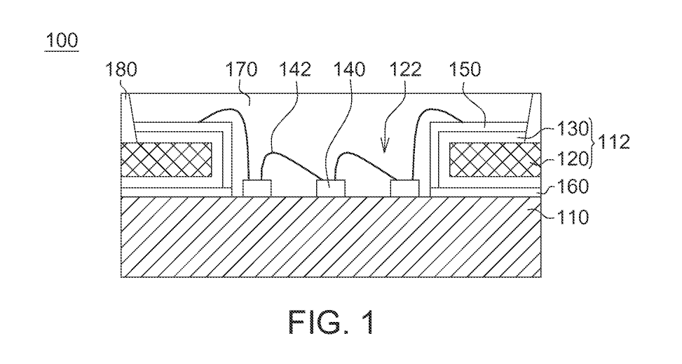

FIG. 1 shows a package structure of a semiconductor light emitting device according to an embodiment of the invention. The package structure 100 of a semiconductor light emitting device 140 comprises a substrate 110, a dielectric layer 120, a circuit board 112, a semiconductor light emitting device 140 and a coating layer 150. The circuit board 112 is formed by the dielectric layer 120 and a circuit layer 130 covering the dielectric layer 120. The circuit board 112 is disposed on the substrate 110 and has an opening portion 122 for exposing the surface of the substrate 110. The semiconductor light emitting device 140 is disposed on the surface of the substrate 110 exposed by the opening portion 112. The coating layer 150 is formed on the surface of the circuit board 112, and covers the sidewalls of the dielectric layer 120, the circuit layer 130 and the opening portion 122. Moreover, an adhesive layer 160 is interposed between the circuit board 112 and the substrate 110 for bonding the circuit board 112 and the substrate 110. In addition, the semiconductor light emitting device 140 is electrically connected to the circuit layer 130 of the circuit board 112 by the conductive wires 142 formed by the wire bonding process, and two adjacent semiconductor light emitting devices 140 can be connected in parallel or serial by the conductive wires 142 to form a circuit. Also, a sealant layer 170 can further be formed over the semiconductor light emitting device 14 to cover the semiconductor light emitting device 140 and its surrounding packages.

Referring to FIG. 1. The semiconductor light emitting device 140 can be formed by a plurality of light emitting diodes. The semiconductor light emitting device 140 is disposed on the substrate 110 formed by a metal with high reflectivity, such that the heat generated by the semiconductor light emitting device 140 can be quickly dissipated to the exterior via the substrate 110. The substrate 110 is formed by a metal or a metal compound, and preferably is a copper base or aluminum base heat dissipation substrate or a substrate formed by a compound such as alumina and aluminum nitride or a composite material.

The dielectric layer 120 is formed by a fiberglass resin and preferably is glass epoxy phenolic or bismaleimide triazine (BT), and is covered by a circuit layer 130, such as a copper layer, to form a circuit board 112. In an embodiment, the circuit board 112 is a metal substrate formed by laminating two metal layers (not etched) and a dielectric layer 120, and an opening portion 122 is formed by removing a part of the metal layers and the dielectric layer 120 by the punch or cutting process. Then, a conductive layer surrounding the opening portion 122 is formed on the metal substrate for connecting two metal layers, and a circuit layer 130 is formed on the dielectric layer 120 by patterning the metal layer and the conductive layer by the etching process.

After the circuit board 112 is formed, the circuit board 112 can be fixed on the substrate 110 through an adhesive layer 160. Then, a coating layer 150 is formed around the opening portion 122, and at least covers the sidewalls of the opening portion 122. As indicated in FIG. 1, the coating layer 150 is formed on the circuit board 112, and covers the sidewalls of the opening portion 122. The coating layer 150 may be a metal layer formed by the electroplating process or a polymer layer (such as a silicone layer) formed by the spraying process. The coating layer 150 is attached on the sidewalls of the circuit board 112, and covers the sidewalls of the dielectric layer 120. By disposing a coating layer 150 on the sidewalls of the opening portion 122 of the circuit board 112, the problems of the sidewalls of the circuit board 112 being deteriorated and etiolated can be resolved in the invention.

Then, the semiconductor light emitting device 140 is fixed on the substrate 110 and located in the opening portion 122. The semiconductor light emitting device 140 can be electrically connected to the circuit layer 130 (or an electroplated metal layer) through the conductive wires 142 formed by the wire bonding process. The semiconductor light emitting device 140 can generate electroluminescence effect when receiving a voltage applied by the circuit layer 130. Lastly, the sealant layer 170 is interposed into an area defined by a reflective cup 180, the circuit board 112 and the substrate 110 for covering the semiconductor light emitting device 140 and its surrounding packages, not only reducing the risk of the conductive wires 142 breaking up but also increasing the overall yield rate.

While the invention has been described by way of example and in terms of the preferred embodiment(s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A package structure of a semiconductor light emitting device, comprising:
a substrate;
a circuit board disposed on the substrate and having an opening portion for exposing a surface of the substrate;
a semiconductor light emitting device disposed on the surface of the substrate exposed by the opening portion; and
a coating layer covering sidewalls of the opening portion and the circuit board.

2. The package structure according to claim 1, wherein the circuit board comprises a dielectric layer and a circuit layer covering top and bottom surfaces of the dielectric layer.

3. The package structure according to claim 2, wherein the coating layer is a metal plating layer or a silicone layer.

4. The package structure according to claim 3, wherein the metal plating layer is formed by silver or nickel.

5. The package structure according to claim 2, wherein the circuit layer is formed by copper.

6. The package structure according to claim 2, wherein the dielectric layer is formed by fiberglass resin.

7. The package structure according to claim 1, further comprising a plurality of conductive wires electrically connected between the semiconductor light emitting device and the circuit board.

8. The package structure according to claim 1, further comprising an adhesive layer bonded between the circuit board and the substrate.

9. The package structure according to claim 1, further comprising a sealant layer covering the semiconductor light emitting device.

10. The package structure according to claim 1, wherein the semiconductor light emitting device is formed by light emitting diodes.
